(19) United States
(12) Patent Application Publication
(10) Pub. No.: US 2025/0253576 A1
(43) Pub. Date: Aug. 7, 2025

(54) Connector Housing Assembly, Connector and Connector Assembly

(71) Applicants: TE Connectivity India Private Limited, Bangalore (IN); TE Connectivity Solutions GmbH, Schaffhausen (CH); Tyco Electronics (Shanghai) Co., Ltd., Shanghai (CN)

(72) Inventors: WenYu (Vindy) Liu, Shanghai (CN); Guangming (Suny) Zhao, Shanghai (CN); Remesh Kuzhikkali, Bangalore (IN); Arjun P, Bangalore (IN); Tao Peng, Shanghai (CN); Haw Jer Shyu, Schaffhausen (CH)

(73) Assignees: TE Connectivity India Private Limited, Bangalore (IN); TE Connectivity Solutions GmbH, Schaffhausen (CH); Tyco Electronics (Shanghai) Co., Ltd., Shanghai (CN)

(21) Appl. No.: 19/046,700

(22) Filed: Feb. 6, 2025

(30) Foreign Application Priority Data
Feb. 6, 2024 (CN) 202410172182.4

(51) Int. Cl. H01R 13/46; H01R 12/72

(52) U.S. Cl. CPC H01R 13/46; H01R 12/722

(57) ABSTRACT

A connector housing assembly includes a housing, a radiator installed on a top of the housing, and a liquid cooling block installed on the top of the housing and the radiator. The liquid cooling block is in thermal contact with the radiator. The liquid cooling block, the housing, and the radiator are assembled into an integral piece.

### CROSS-REFERENCE TO RELATED APPLICATIONS

This application claims the benefit of the filing date under 35 U.S.C. § 119(a)-(d) of Chinese Patent Application No. 202410172182.4 filed on Feb. 6, 2024.

### FIELD OF THE INVENTION

The present invention relates to a connector housing assembly, a connector comprising the connector housing assembly and a connector assembly comprising the connector.

### BACKGROUND OF THE INVENTION

To dissipate heat from a connector, it is sometimes necessary not only to install a radiator on a housing of the connector, but also to install a liquid cooling block on the connector housing, which is in thermal contact with the radiator and the housing. To install and fix the liquid cooling block, it is usually necessary to set several support columns on a circuit board. The liquid cooling block is supported on the support columns and fixed to them with screws. In the prior art, the liquid cooling block is separated from the housing, and users need to install and fix the liquid cooling block separately, which can lead to complex installation steps and inconvenient use of the connector.

### SUMMARY OF THE INVENTION

A connector housing assembly includes a housing, a radiator installed on a top of the housing, and a liquid cooling block installed on the top of the housing and the radiator. The liquid cooling block is in thermal contact with the radiator. The liquid cooling block, the housing, and the radiator are assembled into an integral piece.

### BRIEF DESCRIPTION OF DRAWINGS

The invention will now be described by way of example with reference to the accompanying figures, of which:

FIG. 1 is a perspective view of a connector housing assembly according to an embodiment;

FIG. 2 is an exploded view of the connector housing assembly of FIG. 1;

FIG. 3 is a perspective bottom view of a liquid cooling block of the connector housing assembly of FIG. 1;

FIG. 4 is a transverse sectional view of the connector housing assembly of FIG. 1 with the liquid cooling block separated from a housing of the connector housing assembly;

FIG. 5 is a transverse sectional view of the connector housing assembly of FIG. 1 with the liquid cooling block installed on the housing;

FIG. 6 is a longitudinal sectional view of the connector housing assembly of FIG. 1 with the liquid cooling block separated from the housing;

FIG. 7 is a longitudinal sectional view of the connector housing assembly of FIG. 1 with the liquid cooling block installed on the housing;

FIG. 8 is a perspective view of a connector housing assembly according to another embodiment;

FIG. 9 is a top exploded view of the connector housing assembly of FIG. 8;

FIG. 10 is a bottom exploded view of the connector housing assembly of FIG. 8;

FIG. 11 is a bottom assembly view of the connector housing assembly of FIG. 8;

FIG. 12 is a perspective view of a connector housing assembly according to another embodiment;

FIG. 13 is a transverse sectional view of the connector housing assembly of FIG. 12 with the liquid cooling block separated from a housing of the connector housing assembly;

FIG. 14 is a transverse sectional view of the connector housing assembly of FIG. 12 with the liquid cooling block assembled onto the housing;

FIG. 15 is a longitudinal sectional view of the connector housing assembly of FIG. 12 with the liquid cooling block separated from the housing;

FIG. 16 is a longitudinal sectional view of the connector housing assembly of FIG. 12 with the liquid cooling block assembled onto the housing;

FIG. 17 is a bottom perspective view of the liquid cooling block of the connector housing assembly of FIG. 12;

FIG. 18 is a bottom exploded view of the liquid cooling block of the connector housing assembly of FIG. 12;

FIG. 19 is a perspective view of a pair of movable blocks and an elastic member of the connector housing assembly of FIG. 12;

FIG. 20 is a perspective view of a connector housing assembly according to another embodiment;

FIG. 21 is an exploded view of the connector housing assembly of FIG. 20;

FIG. 22 is a perspective bottom view of a liquid cooling block of the connector housing assembly of FIG. 20;

FIG. 23 is a transverse sectional view of the connector housing assembly of FIG. 20; and

FIG. 24 is a longitudinal sectional view of the connector housing assembly of FIG. 20.

### DETAILED DESCRIPTION

Exemplary embodiments of the present disclosure will be described hereinafter in detail with reference to the attached figures, wherein like reference numerals refer to like elements. The present disclosure may, however, be embodied in many different forms and should not be construed as being limited to the exemplary embodiments set forth herein; rather, these embodiments are provided so that the present disclosure will fully convey the concept of the disclosure to those skilled in the art.

In the following detailed description, for purposes of explanation, numerous specific details are set forth to provide a thorough understanding of the disclosed embodiments. It will be apparent, however, that one or more embodiments may be practiced without these specific details. In other instances, well-known structures and devices are schematically shown to simplify the drawing.

As used herein, an element recited in the singular and preceded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

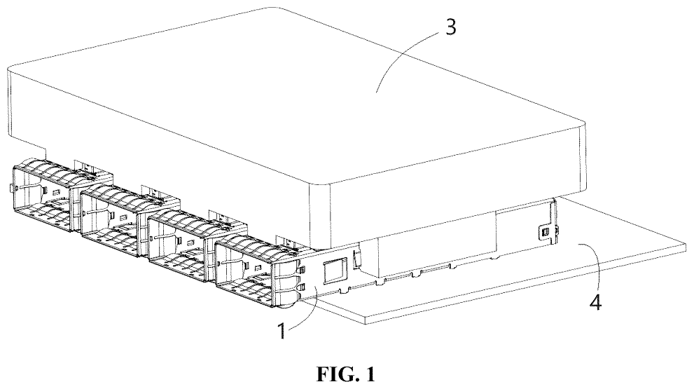

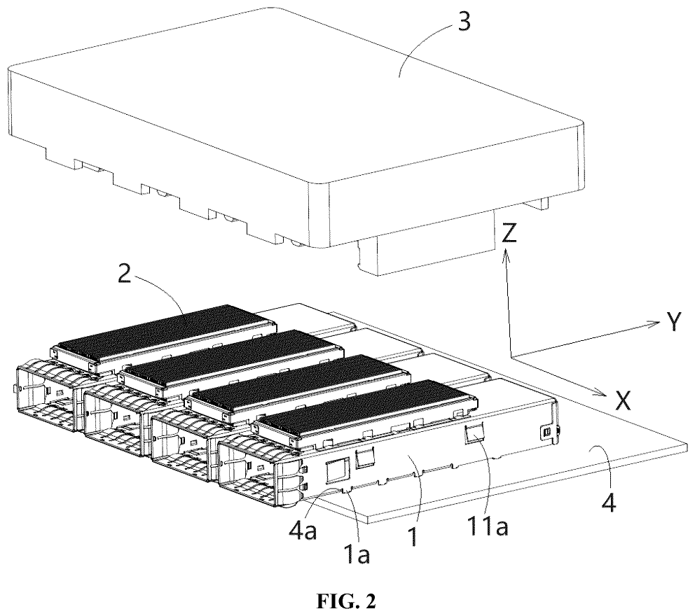

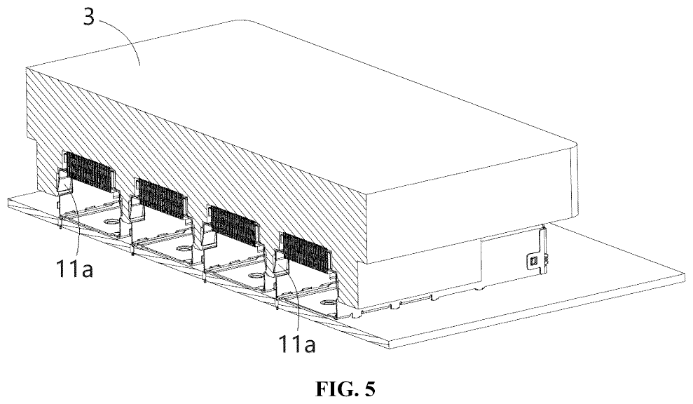

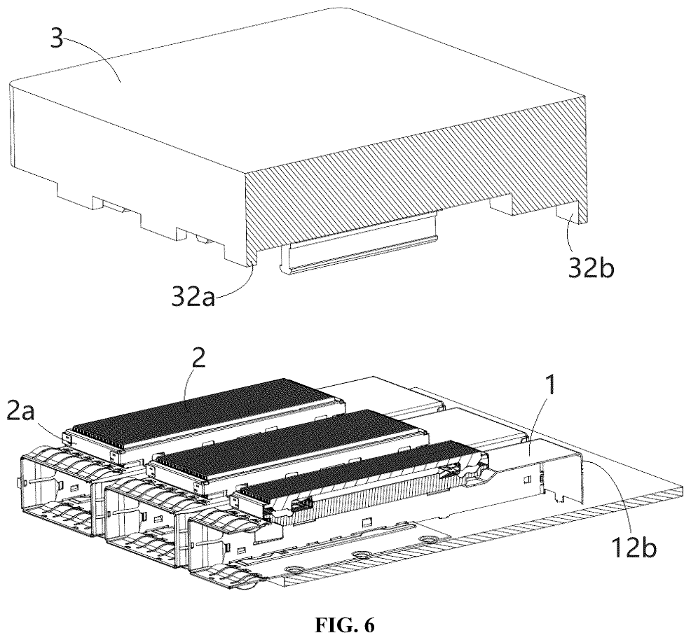

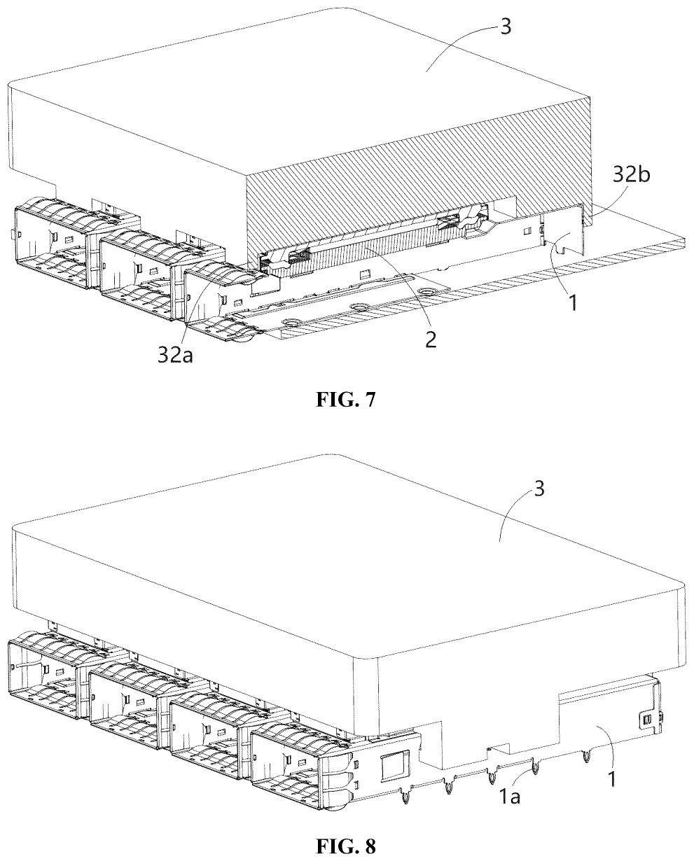

A connector housing assembly according to an exemplary embodiment shown in FIGS. 1-7 is now described. The connector housing assembly comprises a housing 1, a radiator 2, and a liquid cooling block 3. The radiator 2, as shown in FIGS. 2, 4, and 6, is installed on a top of the housing 1. The liquid cooling block 3 is installed on the top of the housing 1 and a top of the radiator 2 as shown in FIGS. 5 and 7. The liquid cooling block 3, the housing 1, and the radiator 2 are assembled into an integral component. As shown in FIGS. 5 and 7, the liquid cooling block 3 is in thermal contact with the radiator 2.

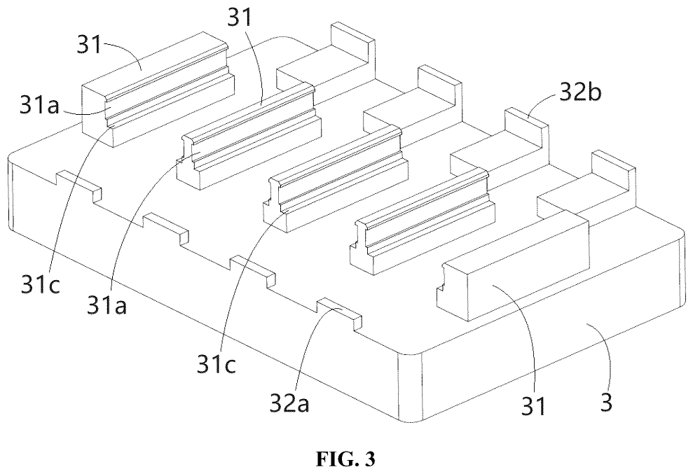

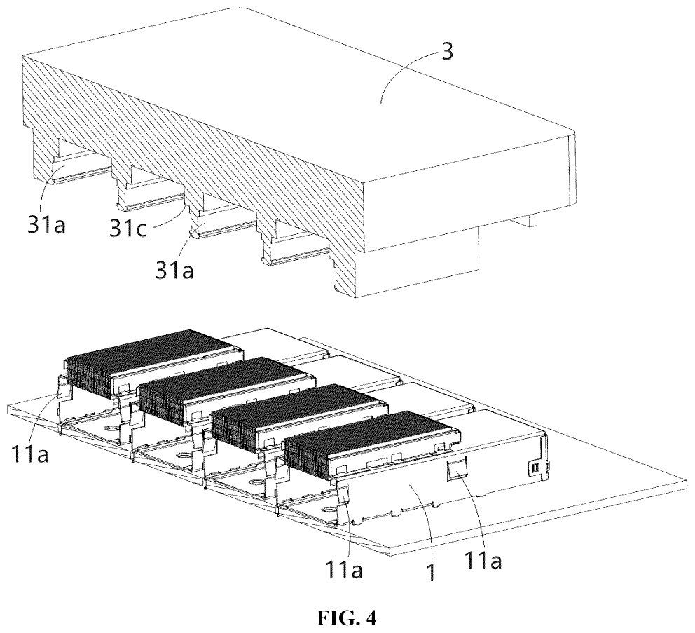

As shown in FIG. 3, the housing 1 has an installation rib 31 extending along the longitudinal direction Y of the housing 1. The installation rib 31 is formed on the bottom of the liquid cooling block 3, and a snap slot 31a, as shown in FIGS. 3-4, is formed on the side of the installation rib 31. The housing 1 has two opposite side walls in its transverse direction X, and an clastic piece 11a, as shown in FIGS. 2, 5, and 7, is formed on the side wall of the housing 1. The elastic piece 11a is engaged with the snap slot 31a to lock the liquid cooling block 3 to the housing 1.

As shown in FIGS. 2, 5, and 7, the elastic piece 11a extends obliquely outward and downward from the side wall of the housing 1 to allow the liquid cooling block 3 to be assembled downward along the height direction Z of the housing I onto the top of the housing 1. The lower end surface of the clastic piece 11a is pressed against the inner side surface of the snap slot 31a, so that the liquid cooling block 3 installed on the housing I cannot be moved upward along the height direction Z of the housing 1.

As shown in FIGS. 3-4, a limit shoulder 31c is formed on the installation rib 31, which is pressed against the edge of the top surface of the housing 1 when the liquid cooling block 3 is installed on the housing 1, so that the liquid cooling block 3 installed on the housing I cannot be moved downward in the height direction Z relative to the housing 1.

As shown in FIGS. 3 and 6-7, a front limit wall 32a and a rear limit wall 32b perpendicular to the longitudinal direction Y of the housing I are formed on the bottom of the liquid cooling block 3. The front limit wall 32a is attached to the front end face 2a of the radiator 2, and the rear limit wall 32b is attached to the rear end face 12b of the housing 1, so that the liquid cooling block 3 cannot be moved in the longitudinal direction Y.

As shown in FIGS. 1-2, 4, and 6-7, the connector housing assembly includes multiple housings 1 and multiple radiators 2. The multiple radiators 2 are respectively mounted on the multiple housings 1. The multiple housings I are arranged in a row in the transverse direction X of the housings 1. Multiple installation ribs 31, as shown in FIG. 3, are formed on the bottom of the liquid cooling block 3 and arranged in a row in the transverse direction X of the housing 1, and each housing 1 is clamped between the corresponding two installation ribs 31, so that the liquid cooling block 3 cannot be moved in the transverse direction X.

As shown in FIGS. 3-4, the snap slots 31a are respectively formed on the inner sides of the outermost two installation ribs 31 in the row of installation ribs 31, for respectively engaging with the elastic pieces 11a on the outer side walls of the outermost two housings 1 in the row of housings 1. The snap slots 31a are respectively formed on both sides of any installation rib 31 except for the outermost two installation ribs 31 in the row of installation ribs 31, for respectively engaging with the elastic pieces 11a on the side walls of adjacent two housings 1.

The liquid cooling block 3 has a liquid cooling channel. The liquid cooling channel is formed in the liquid cooling block 3 to allow the coolant to flow through, and the liquid cooling channel has an inlet for connecting to an inlet pipe and an outlet for connecting to an outlet pipe.

The connector housing assembly according to FIGS. 1-7 further comprises an inlet pipe and an outlet pipe. The inlet pipe is connected to the inlet of liquid cooling block 3. The outlet pipe is connected to the outlet of liquid cooling block 3.

A connector according to an exemplary embodiment is now described. The connector comprises the connector housing assembly according to FIGS. 1-7 and a terminal module. The terminal module is installed in the housing 1. The terminal module has an insulator and terminals arranged in the insulator. One end of the terminal is used to mate with a mating terminal of a mating connector inserted into the housing 1, and the other end of the terminal is used to electrically connect with a circuit board 4.

A connector assembly according to an exemplary embodiment is now described. The connector assembly comprises the connector having the connector housing assembly according to FIGS. 1-7, and the circuit board 4 as shown in FIG. 2. The connector is installed onto the circuit board 4. The bottom of the housing 1 of the connector is fixed to the circuit board 4, and the terminals of the connector are electrically connected to the circuit board 4.

As shown in FIG. 2, a pin la is formed at the bottom of the housing 1 of the connector, and a hole 4a is formed in the circuit board 4. The pin la is press fit into the hole 4a to fix the connector to the circuit board 4.

The connector assembly further comprises a mating connector, which is mated with the connector. The mating connector includes mating terminals, which are inserted into the housing 1 of the connector and mated with the terminals.

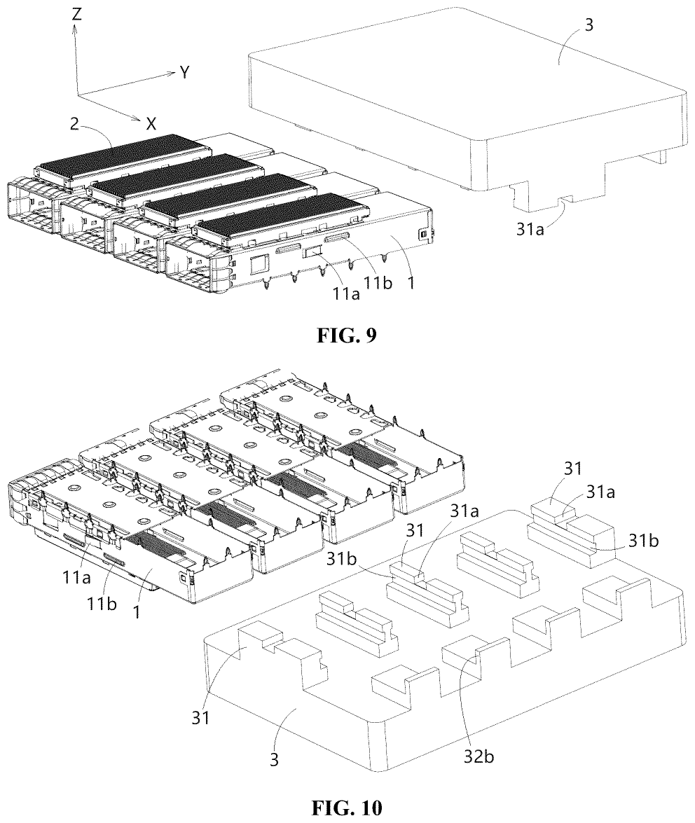

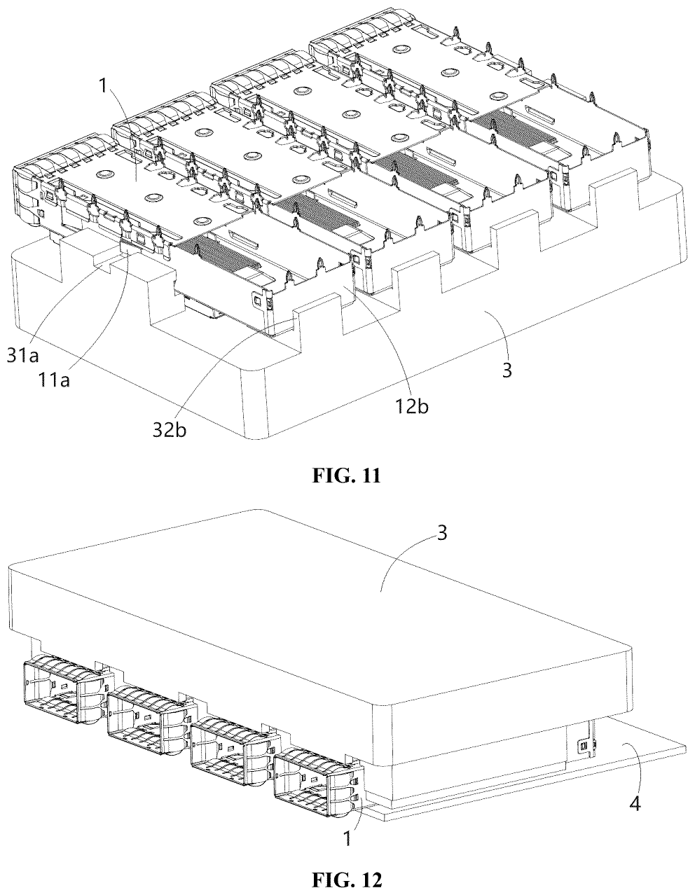

A connector housing assembly according to another exemplary embodiment shown in FIGS. 8-11 is now described. The connector housing assembly comprises a housing 1, a radiator 2, and a liquid cooling block 3. The radiator 2, as shown in FIG. 9, is installed on a top of the housing 1. The liquid cooling block 3 is installed on the top of the housing 1 and a top of the radiator 2 as shown in FIGS. 8 and 11. The liquid cooling block 3, the housing 1, and the radiator 2 are assembled into an integral component. The liquid cooling block 3 is in thermal contact with the radiator 2.

As shown in FIG. 10, the liquid cooling block 3 has an installation rib 31 extending along the longitudinal direction Y of the housing 1. The installation rib 31 is formed on the bottom of the liquid cooling block 3, and a snap slot 31a, as shown in FIGS. 9-11, is formed on the side of the installation rib 31. The housing I has two opposite side walls in its transverse direction X, and an elastic piece 11a is formed on the side wall of the housing 1. The elastic piece 11a is engaged with the snap slot 31a to lock the liquid cooling block 3 to the housing 1.

As shown in FIG. 11, the elastic piece 1 la extends obliquely outward and forward from the side wall of the housing 1 to allow the liquid cooling block 3 to be assembled onto the housing 1 from the rear to the front along the longitudinal direction Y of the housing 1. A front end face of the elastic piece 11a is pressed against the inner surface of the snap slot 31a, so that the liquid cooling block 3 installed on the housing I cannot be moved backward along the longitudinal direction Y of the housing 1.

As shown in FIGS. 10-11, a rear limit wall 32b perpendicular to the longitudinal direction Y of the housing 1 is formed on the bottom of the liquid cooling block 3, which is pressed against the rear end face 12b of the housing 1, so that the liquid cooling block 3 installed on the housing I cannot be moved forward along the longitudinal direction Y of the housing 1.

As shown in FIGS. 9-10, a guide rib 11b extending along the longitudinal direction Y of the housing 1 is formed on the outer side of the side wall of the housing 1. As shown in FIG. 10, a guide slot 31b extending along the longitudinal direction Y of the housing 1 is formed on the side of the installation rib 31. The guide rib 11b cooperates with the guide slot 31b to guide the liquid cooling block 3 to be installed on the housing 1 along the longitudinal direction Y.

As shown in FIG. 10, the guide slot 31b has upper and lower inner sides perpendicular to the height direction Z of the housing 1. The guide rib 11b rests against the lower inner side of the guide slot 31b, and the edge of the top surface of the housing 1 rests against the upper inner side of the guide slot 31b, so that the liquid cooling block 3 installed on the housing 1 cannot be moved in the height direction Z of the housing 1.

As shown in FIGS. 9 and 11, the connector housing assembly includes multiple housings 1 and multiple radiators 2 respectively mounted on the multiple housings 1. The multiple housings 1 are arranged in a row in the transverse direction X of the housings 1. Multiple installation ribs 31 are formed on the bottom of the liquid cooling block 3 and arranged in a row in the transverse direction X of the housing 1. Each housing 1 is clamped between the corresponding two installation ribs 31, so that the liquid cooling block 3 cannot be moved in the transverse direction X.

As shown in FIG. 10, the snap slots 31a are respectively formed on the inner sides of the outermost two installation ribs 31 in the row of installation ribs 31, for respectively engaging with the clastic pieces 11a on the outer side walls of the outermost two housings 1 in the row of housings 1. The snap slots 31a are respectively formed on both sides of any installation rib 31 except for the outermost two installation ribs 31 in the row of installation ribs 31, for respectively engaging with the elastic pieces 11a on the side walls of adjacent two housings 1.

A liquid cooling channel is formed in the liquid cooling block 3 to allow the coolant to flow through. The liquid cooling channel has an inlet for connecting to an inlet pipe and an outlet for connecting to an outlet pipe.

The connector housing assembly according to FIGS. 8-11 further comprises an inlet pipe and an outlet pipe. The inlet pipe is connected to the inlet of the liquid cooling block 3. The outlet pipe is connected to the outlet of the liquid cooling block 3.

A connector according to another exemplary embodiment of the present invention is now described. The connector includes the connector housing assembly according to FIGS. 8-11 and a terminal. The terminal module is installed in the housing 1. The terminal module has an insulator and terminals arranged in the insulator. One end of the terminal is used to mate with a mating terminal of a mating connector inserted into the housing 1, and the other end is used to electrically connect with a circuit board 4.

A connector assembly according to another exemplary embodiment of the present invention is now described. The connector assembly comprises the connector having the connector housing assembly according to FIGS. 8-11 and a circuit board 4. The connector is installed onto the circuit board 4. The bottom of the housing 1 of the connector is fixed to the circuit board 4, and the terminals of the connector are electrically connected to the circuit board 4.

As shown in FIG. 8, a pin la is formed at the bottom of the connector housing 1, and a hole 4a is formed in the circuit board 4. The pin 1a is press fit into the hole 4a to fix the connector to the circuit board 4.

The connector assembly further includes a mating connector which is mated with the connector. The mating connector includes mating terminals which are inserted into the housing 1 of the connector and mated with the terminals.

A connector housing assembly according to another exemplary embodiment shown in FIGS. 12-19 is now described. The connector housing assembly comprises a housing 1, a radiator 2, and a liquid cooling block 3. The radiator 2 is installed on the top of the housing 1. The liquid cooling block 3 is installed on the top of the housing 1 and the radiator 2. The liquid cooling block 3, the housing 1, and the radiator 2 are assembled into an integral component, and the liquid cooling block 3 is in thermal contact with the radiator 2.

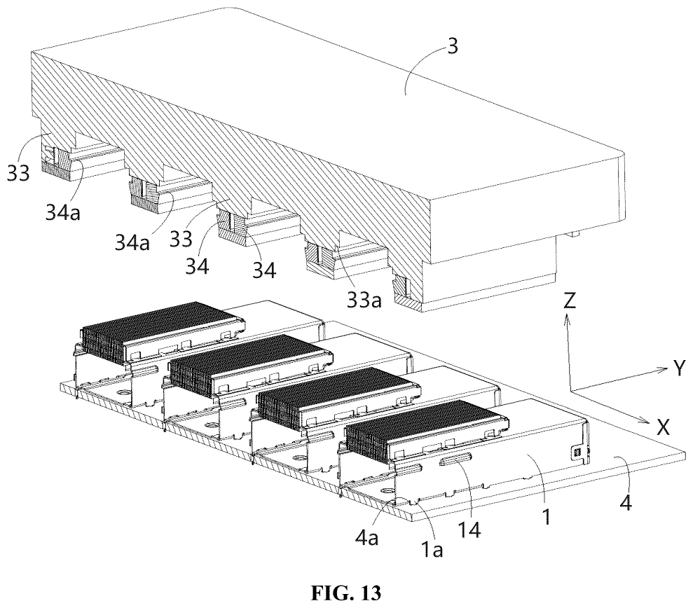

As shown in FIGS. 13 and 17-18, an installation block 33 extending along the longitudinal direction Y of the housing 1 is formed on the bottom of the liquid cooling block 3, and an installation slot 330 is formed on the installation block 33.

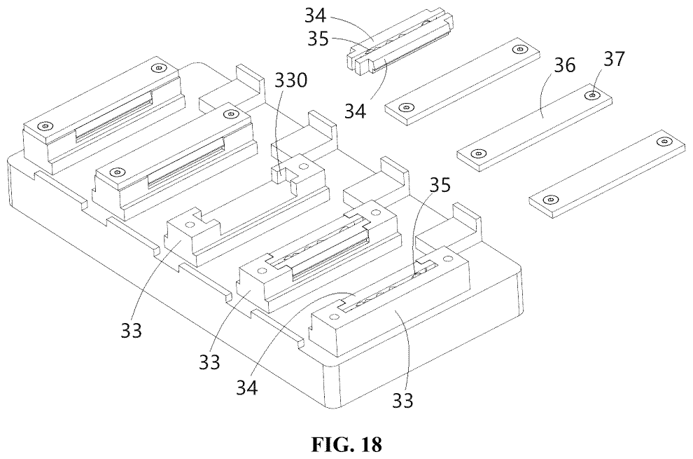

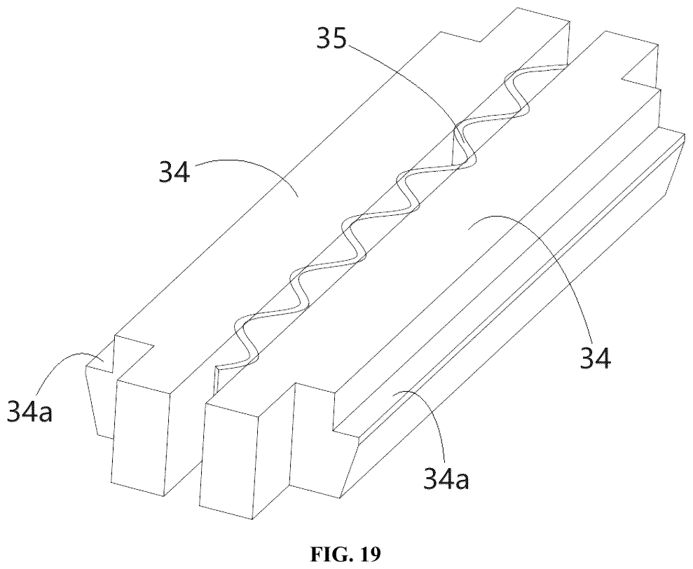

The connector housing assembly also includes a movable block 34 and an elastic member 35, as shown in FIG. 18. The movable block 34 is installed in the installation slot 330 in a movable manner, and can be moved along the transverse direction X of the housing 1 between a locking position engaged with the housing 1 and an unlocking position separated from the housing 1. The clastic member 35 is set in the installation slot 330 and pushes the movable block 34 to the locking position. When the liquid cooling block 3 is installed on the housing 1, the movable block 34 is pushed by the elastic member 35 to the locking position engaged with the housing 1 to lock the liquid cooling block 3 to the housing 1.

As shown in FIGS. 17-18, the connector housing assembly further comprises a mounting plate 36 and screws 37. The mounting plate 36 is installed onto the bottom opening of the installation slot 330 to restrict the movable block 34 within the installation slot 330. The screw 37 passes through the mounting plate 36 and is threaded to the installation block 33 to secure the mounting plate 36 to the installation block 33.

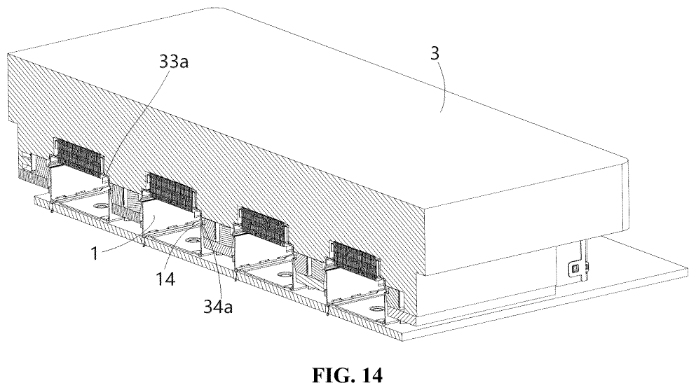

As shown in FIG. 13, the housing 1 has two opposite side walls in its transverse direction X. As shown in FIGS. 13-14, a convex rib 14 extending along the longitudinal direction Y of the housing 1 is formed on the side wall of the housing 1. A hook 34a, as shown in FIGS. 13 and 19, is formed on the side of the movable block 34. When the liquid cooling block 3 is installed on the housing 1, the hook 34a engages with the convex rib 14, preventing the liquid cooling block 3 from being moved upward along the height direction Z of the housing 1 relative to the housing 1.

As shown in FIG. 13, a limit step 33a is formed on the installation block 33. The limit step 33a, as shown in FIG. 14, is pressed against the edge of the top surface of the housing 1 when the liquid cooling block 3 is installed on the housing 1, so that the liquid cooling block 3 installed on the housing 1 cannot be moved downward in the height direction Z relative to the housing 1.

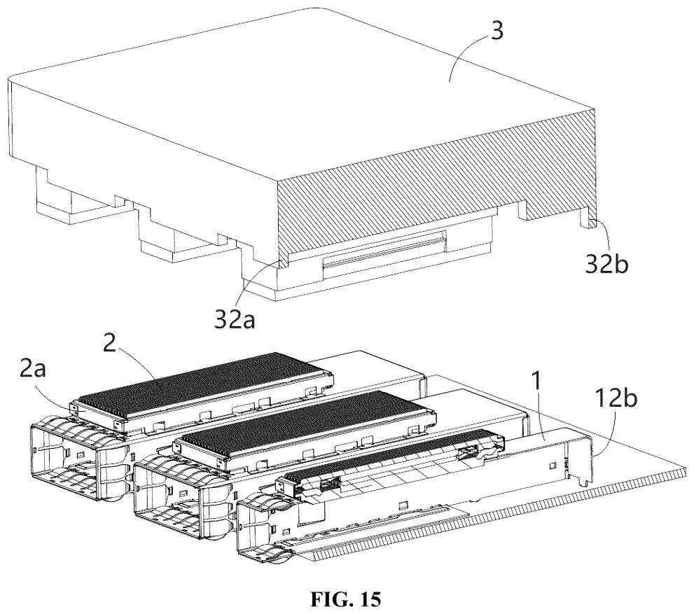

As shown in FIGS. 13 and 15, the connector housing assembly includes multiple housings 1 and multiple radiators 2 respectively mounted on the multiple housings 1. The multiple housings 1 are arranged in a row in the transverse direction X of the housing 1. Multiple installation blocks 33 are formed on the bottom of the liquid cooling block 3 and arranged in a row in the transverse direction X of the housing 1. Each housing 1 is clamped between the corresponding two installation blocks 33, so that the liquid cooling block 3 cannot be moved in the transverse direction X.

As shown in FIG. 18, the movable blocks 34 are respectively installed in the installation slots 330 of the outermost two installation blocks 33 in the row of installation blocks 33, for respectively engaging with the convex ribs 14 on the outer side walls of the outermost two housings 1 in the row of housings 1. A pair of movable blocks 34 are installed in the installation slot 330 of any installation block 33 except for the outermost two installation blocks 33 in the row of installation blocks 33, for respectively engaging with the convex ribs 14 on the side walls of adjacent two housings 1.

As shown in FIG. 18, the clastic member 35 in the installation slot 330 of the outermost installation block 33 in the row of installation blocks 33 is compressed between the movable block 34 and the inner surface of the installation slot 330. The elastic member 35 in the installation slot 330 of any installation block 33 except for the outermost two installation blocks 33 in the row of installation blocks 33 is compressed between the pair of movable blocks 34.

As shown in FIG. 19, the elastic member 35 is a wave shaped spring plate. However, the present invention is not limited to the illustrated embodiments, for example, the elastic member 35 may also be a coil spring or other suitable spring.

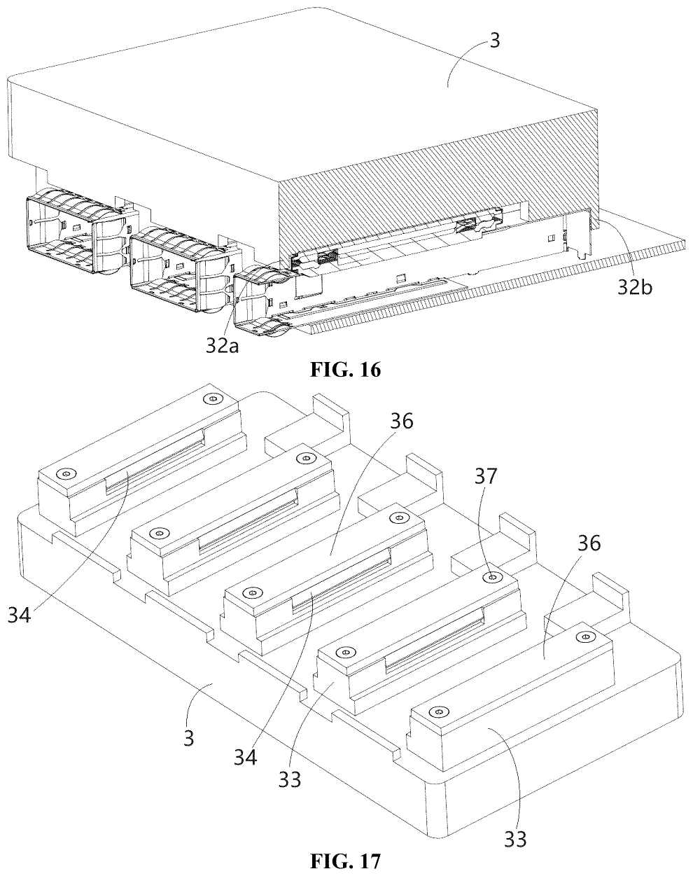

As shown in FIGS. 15-16, a front limit wall 32a and a rear limit wall 32b perpendicular to the longitudinal direction Y of the housing 1 are formed on the bottom of the liquid cooling block 3. The front limit wall 32a is attached to the front end face 2a of the radiator 2, and the rear limit wall 32b is attached to the rear end face 12b of the housing 1, so that the liquid cooling block 3 cannot be moved in the longitudinal direction Y.

A liquid cooling channel is formed in the liquid cooling block 3 to allow the coolant to flow through. The liquid cooling channel has an inlet for connecting to an inlet pipe and an outlet for connecting to an outlet pipe.

The connector housing assembly according to FIGS. 12-19 further includes an inlet pipe and an outlet pipe. The inlet pipe is connected to the inlet of the liquid cooling block 3. The outlet pipe is connected to the outlet of the liquid cooling block 3.

A connector according to another exemplary embodiment is now described. The connector includes the above connector housing assembly according to FIGS. 12-19 and a terminal module. The terminal module is installed in the housing 1. The terminal module has an insulator and terminals arranged in the insulator. One end of the terminal is used to mate with the mating terminal of the mating connector inserted into the housing 1, and the other end is used to electrically connect with a circuit board 4.

A connector assembly according to another exemplary embodiment of the present invention is now described. The connector assembly includes the connector having the connector housing assembly according to FIGS. 12-19 and a circuit board 4. The connector is installed onto the circuit board 4. The bottom of the housing 1 of the connector is fixed to the circuit board 4, and the terminals of the connector are electrically connected to the circuit board 4.

As shown in FIG. 13, a pin la is formed at the bottom of the connector housing 1, and a hole 4a is formed in the circuit board 4. The pin 1a is press fit into the hole 4a to fix the connector to the circuit board 4.

The connector assembly further includes a mating connector which is mated with the connector. The mating connector includes mating terminals which are inserted into the housing 1 of the connector and mated with the terminals.

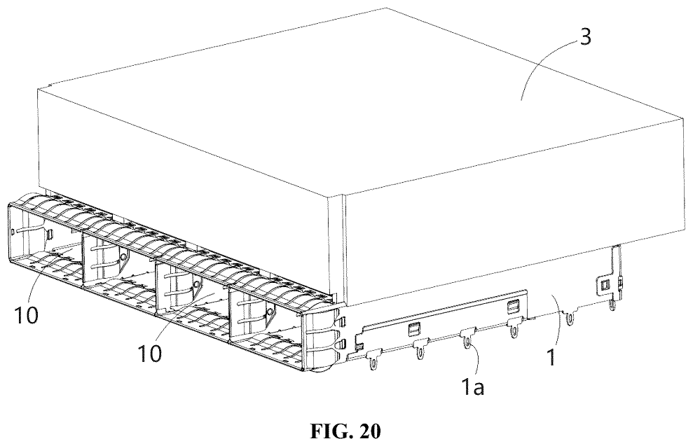

A connector housing assembly according to another exemplary embodiment shown in FIGS. 20-24 is now described. The connector housing assembly comprises a housing 1, a radiator 2, and a liquid cooling block 3. The radiator 2 is installed on the top of the housing 1. The liquid cooling block 3 is installed on the top of the housing 1 and the radiator 2. The liquid cooling block 3, the housing 1, and the radiator 2 are assembled into an integral component, and the liquid cooling block 3 is in thermal contact with the radiator 2. The bottom of the liquid cooling block 3 is welded to the top surface of the housing 1 or bonded to the top surface of the housing 1 with a thermal conductive adhesive.

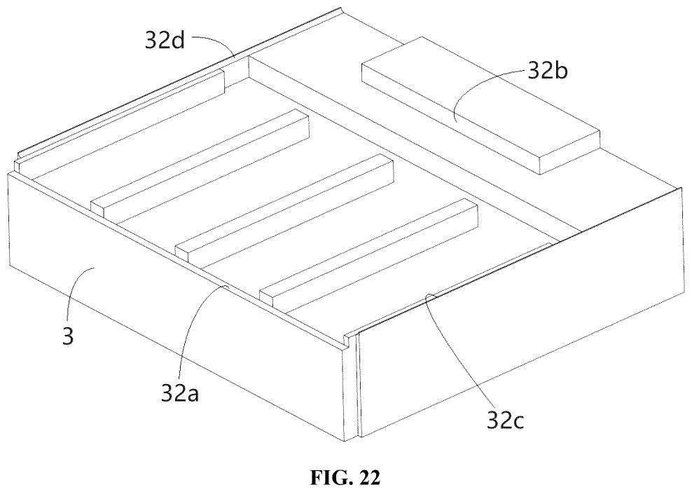

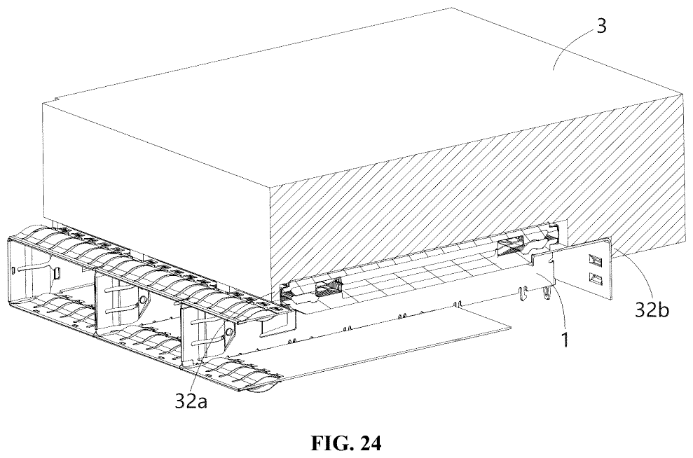

As shown in FIG. 22, a front limit wall 32a and a rear limit wall 32b perpendicular to the longitudinal direction Y of the housing 1 are formed on the bottom of the liquid cooling block 3. As shown in FIG. 24, the front limit wall 32a is attached to the front end face 2a of the radiator 2, and the rear limit wall 32b is attached to the rear end face 12b of the housing 1, so that the liquid cooling block 3 cannot be moved in the longitudinal direction Y.

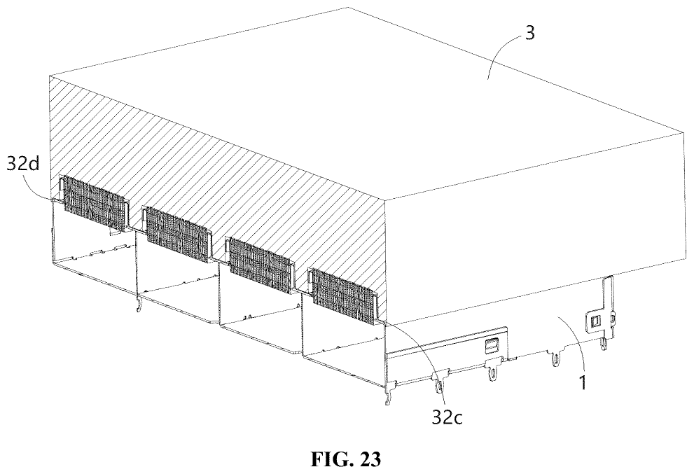

As shown in FIGS. 22-23, left and right limit walls 32c and 32d are respectively formed on the lateral sides of the bottom of the liquid cooling block 3. The left and right limit walls 32c and 32d are respectively pressed against the lateral sides of the housing 1, so that the liquid cooling block 3 cannot be moved in the transverse direction X.

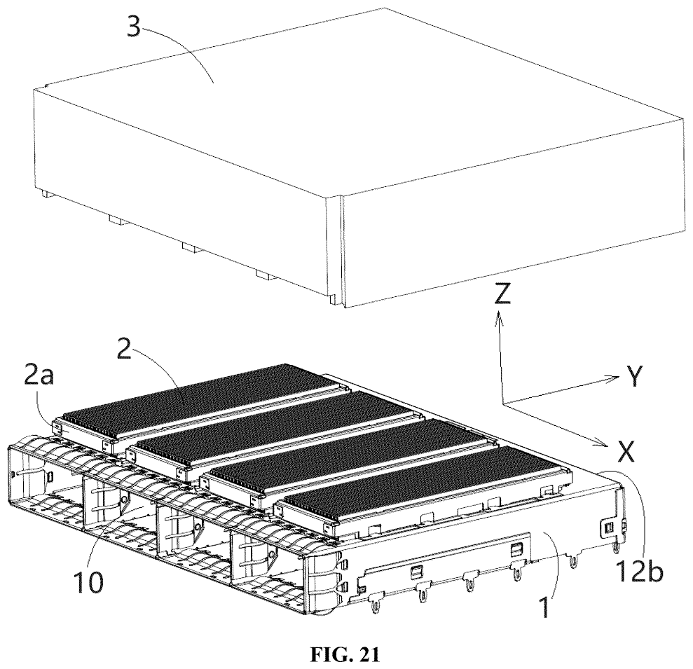

As shown in FIGS. 20-21, the connector housing assembly includes a single housing 1 and multiple radiators 2. Multiple insertion cavities 10 are formed in the single housing 1. The multiple insertion cavities 10 are arranged in a row in the transverse direction X of the housing 1. Multiple radiators 2 are respectively installed on the top walls of the multiple insertion cavities 10.

A liquid cooling channel is formed in the liquid cooling block 3 to allow the coolant to flow through. The liquid cooling channel has an inlet for connecting to an inlet pipe and an outlet for connecting to an outlet pipe.

The connector housing assembly according to FIGS. 20-24 further includes an inlet pipe and an outlet pipe. The inlet pipe is connected to the inlet of the liquid cooling block 3. The outlet pipe is connected to the outlet of the liquid cooling block 3.

A connector according to another exemplary embodiment is now described. The connector includes the connector housing assembly according to FIGS. 20-24 and a terminal module. The terminal module is installed in the housing 1. The terminal module has an insulator and terminals arranged in the insulator. One end of the terminal is used to mate with a mating terminal of a mating connector inserted into the housing 1, and the other end is used to electrically connect with the circuit board 4.

A connector assembly according to another exemplary embodiment is now described. The connector assembly includes the connector having the connector housing assembly according to FIGS. 20-24 and a circuit board 4. The connector is installed onto the circuit board 4. The bottom of the housing 1 of the connector is fixed to the circuit board 4, and the terminals of the connector are electrically connected to the circuit board 4.

As shown in FIG. 20, a pin la is formed at the bottom of the connector housing 1, and a hole 4a is formed in the circuit board 4. The pin la is press fit into the hole 4a to fix the connector to the circuit board 4.

The connector assembly further includes a mating connector which is mated with the connector. The mating connector includes mating terminals which are inserted into the housing 1 of the connector and mated with the terminals.

It should be appreciated for those skilled in this art that the above embodiments are intended to be illustrative, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

In the aforementioned exemplary embodiments according to the present invention, the liquid cooling block, housing, and radiator of the connector are pre-assembled into an integral component, eliminating the step of separately installing and fixing the liquid cooling block and simplifying the installation steps of the connector. Users only need to fix the housing to the circuit board without separately installing and fixing the liquid cooling block, making it very convenient to use.

1. A connector housing assembly, comprising:
a housing;
a radiator installed on a top of the housing; and
a liquid cooling block installed on the top of the housing and the radiator and in thermal contact with the radiator, the liquid cooling block, the housing, and the radiator are assembled into an integral piece.

2. The connector housing assembly of claim 1, wherein an installation rib having a snap slot is formed on a bottom of the liquid cooling block, the snap slot is formed on a side of the installation rib and the installation rib extends along a longitudinal direction of the housing, the housing has a pair of opposite side walls in a transverse direction, and an elastic piece is formed on one of the pair of opposite side walls of the housing, the elastic piece engaging the snap slot to lock the liquid cooling block to the housing.

3. The connector housing assembly of claim 2, wherein the elastic piece extends obliquely outward and downward from the one of the pair of opposite side walls of the housing and the liquid cooling block is assembled downward along a height direction of the housing onto the top of the housing, a lower end surface of the elastic piece is pressed against an inner side surface of the snap slot and stops the liquid cooling block from moving upward along the height direction.

4. The connector housing assembly of claim 3, wherein a limit shoulder is formed on the installation rib, the limit shoulder is pressed against an edge of a top surface of the housing when the liquid cooling block is installed on the housing and stops the liquid cooling block from moving downward in the height direction.

5. The connector housing assembly of claim 2, wherein a front limit wall and a rear limit wall perpendicular to the longitudinal direction are formed on the bottom of the liquid cooling block, the front limit wall is attached to a front end face of the radiator and the rear limit wall is attached to a rear end face of the housing to stop the liquid cooling block from moving in the longitudinal direction.

6. The connector housing assembly of claim 2, wherein the housing is one of a plurality of housings and the radiator is one of a plurality of radiators, each radiator is respectively mounted on one of the housings, the plurality of housings are arranged in a row in the transverse direction, the installation rib is one of a plurality of installation ribs formed on the bottom of the liquid cooling block and arranged in a row in the transverse direction, each housing is clamped between a pair of corresponding installation ribs to stop the liquid cooling block from moving in the transverse direction.

7. The connector housing assembly of claim 6, wherein the snap slot is one of a plurality of snap slots respectively formed on inner sides of two outermost installation ribs in a row of installation ribs and respectively engage with a plurality of elastic pieces on a plurality of outer side walls of two outermost housings in the row of housings.

8. The connector housing assembly of claim 7, wherein the snap slots are respectively formed on a pair of sides of any one of the installation ribs except for an outermost two installation ribs in the row of installation ribs and respectively engage with the elastic pieces on side walls of two adjacent housings.

9. The connector housing assembly of claim 2, wherein the elastic piece extends obliquely outward and forward from the one of the pair of opposite side walls of the housing and the liquid cooling block is assembled onto the housing from a rear to a front along the longitudinal direction, a front end face of the elastic piece is pressed against an inner side face of the snap slot to stop the liquid cooling block from moving backward along the longitudinal direction, and a rear limit wall perpendicular to the longitudinal direction is formed on the bottom of the liquid cooling block, the rear limit wall is pressed against a rear end face of the housing to stop the liquid cooling block from moving forward along the longitudinal direction.

10. The connector housing assembly of claim 9, wherein a guide rib extending along the longitudinal direction is formed on an outer side of the one of the pair of opposite side walls of the housing, and a guide slot extending along the longitudinal direction is formed on a side of the installation rib, the guide rib cooperates with the guide slot to guide the liquid cooling block to be installed onto the housing along the longitudinal direction, the guide slot has an upper inner side and a lower inner side perpendicular to a height direction of the housing, the guide rib rests on the lower inner side of the guide slot, and an edge of a top surface of the housing rests on the upper inner side of the guide slot to stop the liquid cooling block from moving in the height direction.

11. The connector housing assembly of claim 1, wherein an installation block extending along a longitudinal direction of the housing is formed on a bottom of the liquid cooling block, and an installation slot is formed on the installation block.

12. The connector housing assembly of claim 11, further comprising:
a movable block installed in the installation slot in a movable manner and movable along a transverse direction of the housing between a locking position engaged with the housing and an unlocking position separated from the housing;
an elastic member installed in the installation slot for pushing the movable block to the locking position;
a mounting plate installed onto a bottom opening of the installation slot and restricting the movable block within the installation slot; and
a screw passing through the mounting plate and threaded to the installation block fixing the mounting plate to the installation block, and when the liquid cooling block is installed on the housing, the movable block is pushed by the elastic member to the locking position engaged with the housing to lock the liquid cooling block onto the housing.

13. The connector housing assembly of claim 12, wherein the housing has a pair of opposite side walls in a transverse direction, a convex rib extending along the longitudinal direction is formed on a side wall of the housing and a hook is formed on a side of the movable block, when the liquid cooling block is installed on the housing, the hook is engaged with the convex rib to stop the liquid cooling block from moving upward along a height direction of the housing, and a limit step is formed on the installation block, the limit step is pressed against an edge of a top surface of the housing when the liquid cooling block is installed on the housing to stop the liquid cooling block from moving downward in the height direction.

14. The connector housing assembly of claim 13, wherein the housing is one of a plurality of housings and the radiator is one of a plurality of radiators, each radiator is mounted on one housing, the plurality of housings are arranged in a row in the transverse direction, and the installation block is one of a plurality of installation blocks formed on the bottom of the liquid cooling block and arranged in a row in the transverse direction, each housing is clamped between two corresponding installation blocks of the plurality of installation blocks to stop the liquid cooling block from moving in the transverse direction.

15. The connector housing assembly of claim 14, wherein the movable block is one of a plurality of movable blocks respectively installed in the installation slots of an outermost two installation blocks in the row of installation blocks, the movable blocks engage with a plurality of convex ribs on outer side walls of two outermost housings in the row of housings.

16. The connector housing assembly of claim 15, wherein a pair of movable blocks of the plurality of movable blocks are installed in the installation slot of any installation block except for an outermost two installation blocks in the row of installation blocks and engage with a plurality of convex ribs on side walls of two adjacent housings.

17. The connector housing assembly of claim 16, wherein the elastic member in the installation slot of any installation block except for the outermost two installation blocks in the row of installation blocks is compressed between the pair of movable blocks, the elastic member is a wave shaped spring plate or a coil spring.

18. The connector housing assembly of claim 16, wherein the elastic member in the installation slot of an outermost installation block in the row of installation blocks is compressed between the movable block and an inner surface of the installation slot, the elastic member is a wave shaped spring plate or a coil spring.

19. The connector housing assembly of claim 12, wherein a front limit wall and a rear limit wall perpendicular to the longitudinal direction are formed on the bottom of the liquid cooling block, the front limit wall is attached to a front end face of the radiator and the rear limit wall is attached to a rear end face of the housing to stop the liquid cooling block from moving in the longitudinal direction.

20. The connector housing assembly of claim 1, wherein a bottom of the liquid cooling block is welded to a top surface of the housing or bonded to the top surface of the housing with a thermal conductive adhesive.

21. The connector housing assembly of claim 20, wherein a front limit wall and a rear limit wall perpendicular to a longitudinal direction of the housing are formed on the bottom of the liquid cooling block, the front limit wall is attached to a front end face of the radiator and the rear limit wall is attached to a rear end face of the housing to stop the liquid cooling block from moving in the longitudinal direction, and a left limit wall and a right limit wall are respectively formed on a pair of lateral sides of the bottom of the liquid cooling block, the left limit wall and the right limit wall are respectively pressed against a pair of lateral sides of the housing to stop the liquid cooling block from moving in a transverse direction of the housing.

22. The connector housing assembly of claim 20, wherein the connector housing assembly has a single housing and the radiator is one of a plurality of radiators, a plurality of insertion cavities are formed in the single housing, the plurality of insertion cavities are arranged in a row in a transverse direction of the housing, each radiator is installed on a plurality of top walls of one insertion cavity.

23. The connector housing assembly of claim 1, wherein a liquid cooling channel is formed in the liquid cooling block to allow a coolant to flow through, the liquid cooling channel has an inlet and an outlet.

24. The connector housing assembly of claim 23, further comprising an inlet pipe connected to the inlet of the liquid cooling block, and an outlet pipe connected to the outlet of the liquid cooling block.

25. A connector, comprising:
a connector housing assembly having a housing, a radiator installed on a top of the housing, and a liquid cooling block in thermal contact with the radiator and installed on the top of the housing and the radiator, the liquid cooling block, the housing, and the radiator are assembled into an integral piece; and
a terminal module installed in the housing, the terminal module has an insulator and a plurality of terminals arranged in the insulator, an end of the terminal module mates with a mating terminal of a mating connector inserted into the housing, and another end of the terminal electrically connects with a circuit board.
